(19) United States
(12) Patent Application Publication
(10) Pub. No.: US 2023/0223493 A1
(43) Pub. Date: Jul. 13, 2023

(54) SUBSTRATE FOR LED ELEMENT AND IMAGE DISPLAY DEVICE

(71) Applicant: AGC Inc., Tokyo (JP)

(72) Inventors: Hirofumi TOKUNAGA, Tokyo (JP); Kazutaka ONO, Tokyo (JP); Takefumi ABE, Tokyo (JP); Naoya WADA, Tokyo (JP)

(73) Assignee: AGC Inc., Tokyo (JP)

(21) Appl. No.: 18/182,688

(22) Filed: Mar. 13, 2023

Related U.S. Application Data
(63) Continuation of application No. PCT/JP2021/033537, filed on Sep. 13, 2021.

(30) Foreign Application Priority Data
Sep. 14, 2020 (JP) 2020-153811

(51) Int. Cl. H01L 33/20; H01L 25/075

(52) U.S. Cl. CPC H01L 33/20; H01L 25/0753

(57) ABSTRACT

The present invention relates to an LED element substrate on which an LED element is to be provided and which includes a glass, in which at least one main surface of the substrate is black, and one or more LED elements are to be provided on the black main surface, and relates to an LED element substrate on which an LED element is to be provided and which includes a glass, in which at least one main surface of the substrate is black, the substrate comprises a plurality of holes, and one or more LED elements are to be provided on an inside of each of the holes.

### CROSS-REFERENCE TO RELATED APPLICATIONS

This is a continuation of International Application No. PCT/JP2021/033537 filed on Sep. 13, 2021, and claims priority from Japanese Patent Application No. 2020-153811 filed on Sep. 14, 2020, the entire content of which is incorporated herein by reference.

### TECHNICAL FIELD

The present invention relates to an LED element substrate and an image display device.

### BACKGROUND ART

An image display device using a light emitting diode (LED) element is used as various displays such as a large vision, a street advertisement, a digital camera, an in-vehicle display, a notebook PC, and a tablet terminal.

Patent Literatures 1 and 2 disclose an LED image display device using uncolored glass or a synthetic resin substrate as substrates.

### CITATION LIST

### Patent Literature

Patent Literature 1: JP2011-233733A
Patent Literature 2: JP2001-24235A

### SUMMARY OF THE INVENTION

### Technical Problem

In recent years, the case where LED image display devices are used not only indoors but also outdoors increases. In the case where the image display device is exposed to external light, there is a concern of a decrease in contrast ratio that is considered to be caused by irregular reflection that may occur due to surface unevenness, and aged deterioration of a surface member due to ultraviolet rays, moisture, or the like.

The image display devices disclosed in Patent Literatures 1 and 2 have room for improvement in the above problems.

An object of the present invention is to provide an LED element substrate in which a contrast ratio does not decrease and a surface member is less likely to deteriorate even when used outdoors in the case where the LED element substrate is used in an image display device, and an image display device including the substrate.

### Solution to Problem

As a result of intensive studies, the inventors have found that the above problems can be solved by the following substrate and the like.

(1) An LED element substrate on which an LED element is to be provided and which includes a glass, in which

at least one main surface of the substrate is black, and

one or more LED elements are to be provided on the black main surface.

(2) An LED element substrate on which an LED element is to be provided and which includes a glass, in which

at least one main surface of the substrate is black,

the substrate includes a plurality of holes, and

one or more LED elements are to be provided on an inside of each of the holes.

(3) The LED element substrate according to (2), in which each of the holes has a tapered shape.
(4) The LED element substrate according to (2) or (3), in which each of the holes includes a reflective film on an inner surface of each of the holes.
(5) The LED element substrate according to any one of (1) to (4), in which the glass is colored black or includes a black film on at least one main surface of the substrate.
(6) An image display device including: the LED element substrate according to any one of (1) to (5); and an LED element.

### Advantageous Effects of Invention

According to the present invention, it is possible to provide an LED element substrate in which a contrast ratio does not decrease and a surface member is less likely to deteriorate even when used outdoors in the case where the LED element substrate is used in an image display device, and an image display device including the substrate.

### BRIEF DESCRIPTION OF DRAWINGS

FIG. 1 is a cross-sectional view according to an embodiment of an image display device of the present invention.

FIG. 2 is a cross-sectional view according to another embodiment of an image display device of the present invention.

FIG. 3 is a cross-sectional view according to another embodiment of an image display device of the present invention.

FIG. 4 is a cross-sectional view according to another embodiment of an image display device of the present invention.

### DESCRIPTION OF EMBODIMENTS

<LED Element Substrate>

An LED element substrate according to the present invention (hereinafter, also referred to as “substrate according to the present invention”) is a substrate on which an LED element is to be mounted.

The substrate according to the present invention includes a glass substrate. By using a glass, which is an inorganic substance, the substrate is excellent in light resistance and weather resistance as compared with a substrate in the related art formed from organic substances such as resin.

In the substrate according to the present invention, at least one main surface is black. Such a surface is an observer side, that is, a front surface of the image display device. In the case where the main surface of the substrate is not black, irregular reflection may occur when the LED element emits light, which may result in a decrease in a contrast ratio. In addition, when used outdoors and exposed to external light, irregular reflection due to surface unevenness may occur, which may result in a decrease in the contrast ratio. Since the main surface of the substrate is black, such irregular reflection is prevented, the contrast ratio is improved, and a tight black color can be displayed.

Examples of the substrate including the black main surface include a substrate that includes a colorless glass substrate and a black film provided on at least one main surface of the glass substrate, and a substrate including a glass which is colored black itself.

<Glass Substrate Including Black Film>

In the glass substrate including the black film, a material of the glass is not particularly limited, and alkali glass, alkali-free glass, or the like can be used. Among these, the alkali-free glass is suitable for outdoor use because there is no risk of elution of an alkali component due to moisture. In addition, the alkali-free glass is also suitable in that it is less likely to cause thermal expansion and is less likely to cause migration of an alkali component due to energization.

As a glass composition, compositions shown below in terms of mole percent based on oxides are preferable.

SiO₂: 50% to 80%, Al₂O₃: 0% to 30%, and Li₂O+Na₂O+K₂O: 0% to 25%

The black film preferably includes, for example, a light absorption layer for blocking light by absorption of visible light and a low refractive index layer for reducing a reflectance of visible light. A good black film can be obtained by having in combination with light-blocking property and low reflectivity. The black film can also be obtained by using Vantablack or a black paste having a reflectance of 4% or less at a wavelength of 380 nm to 650 nm.

From the viewpoint of absorbing visible light, the light absorption layer preferably has an extinction coefficient of 0.4 to 3.5.

Examples of the black film include a structure in which a first light absorption layer, a second light absorption layer, and a low refractive index layer are laminated.

The first light absorption layer is a layer mainly for imparting good light-blocking property to the black film, and is preferably a layer having an extinction coefficient of 2.5 or more. In the case where the extinction coefficient is 2.5 or more, a light transmittance is sufficiently low, and sufficient light-blocking property can be obtained without increasing a film thickness of the light absorption layer.

Specifically, the first light absorption layer preferably contains one or more kinds selected from chromium, molybdenum, tungsten, iron, nickel, titanium, and lower chromium oxide. Here, the term “lower chromium oxide” means chromium oxide having an oxygen defect. Chromium oxide having no oxygen defect hardly absorbs light, whereas chromium oxide having the oxygen defect can be used as a material constituting the first light absorption layer because the extinction coefficient increases due to presence of the oxygen defect.

The first light absorption layer itself has a transmittance of preferably 5% or less, and more preferably 3% or less. From such a viewpoint, the first light absorption layer is preferably constituted of one or more kinds selected from chromium, molybdenum, and tungsten, and a thickness thereof is preferably 40 nm or more, more preferably 50 nm or more. Further, the film thickness of the first light absorption layer is preferably 200 nm or less, and more preferably 180 nm or less so that the entire black film is not unnecessarily thick.

The second light absorption layer is, together with the low refractive index layer, a layer for mainly reducing the reflectance of light incident on a surface of a low refractive index layer formation side in the black film from the external space. From the viewpoint of achieving such an effect, the second light absorption layer is a layer having a refractive index of preferably 1.4 to 3.0 and having an extinction coefficient of preferably 0.4 to 1.0. By satisfying the above ranges for both the refractive index and the extinction coefficient, it is possible to reduce the reflectance of the light incident on the surface of the low refractive index layer formation side in the black film from the external space.

Specifically, the second light absorption layer is preferably constituted of one or more kinds selected from copper oxide, lower silicon oxide, lower titanium oxide, and lower chromium oxide. The lower silicon oxide and the lower titanium oxide mean silicon oxide or titanium oxide having the oxygen defect. An oxide having no oxygen defect hardly absorbs light, whereas an oxide having the oxygen defect can be used as a material constituting the second light absorption layer because the extinction coefficient increases due to the presence of the oxygen defect. Among these, use of one or more kinds selected from copper oxide, lower chromium oxide, and lower titanium oxide each having the refractive index of 1.5 to 2.7 and the extinction coefficient of 0.5 to 0.9 is preferable from the viewpoint of keeping the reflectance low. Further, from the viewpoint of chemical stability of a film material and stability of production in a manufacturing process, use of copper oxide (II) (CuO) is more preferable. Copper oxide (I) (Cu₂O) may be simultaneously produced in the process of producing copper oxide (II) (CuO), and in the case where the refractive index is 1.5 to 2.7 and the extinction coefficient is 0.5 to 0.9, copper oxide (I) (Cu₂O) and copper oxide (II) (CuO) may be mixed and used.

The thickness of the second light absorption layer is preferably 20 nm to 140 nm, and more preferably 25 nm to 50 nm. If the thickness of the second light absorption layer falls within the above range, a low reflectance can be maintained.

The low refractive index layer is a layer having the refractive index of preferably 3.0 or less, more preferably 1.7 or less. In the case where the refractive index is 3.0 or less, it is possible to sufficiently reduce the reflectance of the light incident on the surface of the low refractive index layer formation side in the black film from the external space. Specifically, the low refractive index layer can be constituted of one or more kinds selected from, for example, silicon oxide (SiO₂), magnesium fluoride (MgF₂), aluminum oxide (Al₂O₃), lanthanum fluoride, and sodium aluminum hexafluoride. In order to further reduce the reflectance of light, the low refractive index layer preferably has the refractive index of 1.6 or less, and specifically, as a constituent material thereof, one or more kinds selected from silicon oxide (SiO₂), magnesium fluoride (MgF₂) and alumina (Al₂O₃) are preferably used, and among these, silicon oxide (SiO₂) is preferable used.

The thickness of the low refractive index layer is preferably from 25 nm to 80 nm, and more preferably from 35 nm to 65 nm. In the case where the thickness of the low refractive index layer falls within the above range, a low reflectance can be maintained.

From the viewpoint of light-blocking property, the film thickness of the black film is preferably 300 nm or more, more preferably 500 nm or more. In addition, in the case where the film thickness is too thick, warpage of the glass substrate may occur after film formation, and therefore the film thickness of the black film is preferably 1000 nm or less, more preferably 800 nm or less.

The black film can be formed by a known method disclosed in, for example, JP2013-148844A, JP2016-42196A, and JP2017-167557A, etc.

<Black Glass Substrate>

As a glass having black color, from the viewpoint of absorbing visible light, glass having a minimum absorption coefficient of 0.5 mm⁻¹ or more at a wavelength of 380 nm to 650 nm is preferable.

As the glass having black color, from the viewpoint of uniformly absorbing a visible light region, glass in which the absorption coefficient at a wavelength of 550 nm/the absorption coefficient at a wavelength of 600 nm, and the absorption coefficient at a wavelength of 450 nm/the absorption coefficient at a wavelength of 600 nm are both within the range of 0.7 to 1.2 are more preferable.

As the glass having black color, from the viewpoint of uniformly absorbing visible light region, glass in which each of a change amount ΔT(550/600) of a relative value of the absorption coefficient represented by the following formula (1) and a change amount ΔT(450/600) of a relative value of the absorption coefficient represented by the following formula (2) is 5% or less in terms of an absolute value is more preferable.

ΔT(550/600)(%)=[{A(550/600)−B(550/600)}/A(550/600)]×100 (1)

ΔT(450/600)(%)=[{A(450/600)−B(450/600)}/A(450/600)]×100 (2)

In the above formula (1), A(550/600) is a relative value between the light absorption coefficient at the wavelength of 550 nm and the absorption coefficient at the wavelength of 600 nm, which is calculated based on a spectral transmittance curve of the glass after being irradiated with light from a 400 W high-pressure mercury lamp for 100 hours, and B(550/600) is a relative value between the absorption coefficient at the wavelength of 550 nm and the absorption coefficient at the wavelength of 600 nm, which is calculated based on a spectral transmittance curve of the glass before light irradiation.

In the above formula (2), A(450/600) is a relative value between the light absorption coefficient at the wavelength of 450 nm and the absorption coefficient at the wavelength of 600 nm, which is calculated based on a spectral transmittance curve of the glass after being irradiated with light from a 400 W high-pressure mercury lamp for 100 hours, and B(450/600) is a relative value between the absorption coefficient at the wavelength of 450 nm and the absorption coefficient at the wavelength of 600 nm, which is calculated based on a spectral transmittance curve of the glass before light irradiation.

A material of the glass having black color is not particularly limited, and alkali glass, alkali-free glass, or the like can be used. Among these, the alkali-free glass is suitable for outdoor use because there is no risk of elution of an alkali component due to moisture. In addition, the alkali-free glass is also suitable in that it is less likely to cause thermal expansion and is less likely to cause migration of an alkali component due to energization.

As a glass composition, compositions shown below in terms of mole percent based on oxides are preferable as the main component.

SiO₂: 50% to 80%, Al₂O₃: 0% to 30%, and Li₂O+Na₂O+K₂O: 0% to 25%

Examples of the glass having black color include a glass containing, in addition to the above main component, as a coloring component, one or more kinds of metal oxides such as Ce, Co, Mn, Fe, Er, Ni, Cu, Cr, V, Bi, and Nd. As the coloring component, CeO₂, Co₃O₄, MnO₂, Fe₂O₃, Er₂O₃, NiO, CuO, Cr₂O₃, V₂O₅, Bi₂O₃ and Nd₂O₃ are preferably used.

The glass having black color preferably contains 1% to 12% of these coloring components in terms of mole percent based on oxides.

More specifically, glass containing CeO₂: 0% to 8%, Co₃O₄: 0% to 8%, MnO: 0% to 8%, MnO₂: 0% to 8%, Fe₂O₃: 0.01% to 8%, Er₂O₃: 0% to 8%, NiO: 0% to 8%, CuO: 0% to 8%, Cu₂O: 0% to 8%, Cr₂O₃: 0% to 8%, V₂O₅: 0% to 8%, Bi₂O₃: 0% to 8%, and Nd₂O₃: 0% to 8% is more preferable.

Examples of method for obtaining the glass having black color include known methods disclosed in JP5187463B and JP5682609B.

The substrate according to the present invention includes two modes of a substrate

A including no hole and a substrate B including a plurality of holes. Hereinafter, the modes will be described.

<Substrate A>

In the substrate A, one or more LED elements are to be installed on a black main surface side.

An installation interval of the LED elements is preferably 100 μm to 10000 μm from the viewpoint of resolution.

In the case where the substrate A is a glass substrate with a black film, a thickness of the substrate A is preferably 0.4 mm or more, more preferably 0.5 mm or more, and further preferably 0.7 mm or more in order to prevent warpage after forming the black film. In addition, the thickness is preferably 10 mm or less, more preferably 6 mm or less because a weight increases in the case where the thickness is too thick.

In the case where the substrate A is a black glass substrate, the thickness of the substrate A is preferably 0.5 mm or more, more preferably 0.7 mm or more, and further preferably 1.1 mm or more from the viewpoint of preventing light transmission to a back surface of the substrate, and preferably 10 mm or less, and more preferably 6 mm or less from the viewpoint of the weight.

In the case where the substrate A is a glass substrate with the black film, an average thermal expansion coefficient of the glass in the substrate A at 50° C. to 350° C. is preferably from 20×10⁻⁷/° C. to 130×10⁻⁷/° C., more preferably from 30×10⁻⁷/° C. to 110×10⁻⁷/° C., and particularly preferably from 35×10⁻⁷/° C. to 95×10⁻⁷/° C. in order to prevent the warpage after forming the black film.

In the case where the substrate A is the black glass substrate, the average thermal expansion coefficient of the glass in the substrate A at 50° C. to 350° C. is not particularly limited, and is generally preferably from 5×10⁻⁷/° C. to 150×10⁻⁷/° C.

In the case where the substrate A is a glass substrate with the black film, a Young's modulus of the glass in the substrate A is preferably 45 GPa or more, more preferably 60 GPa or more, and particularly preferably 70 GPa or more in order to prevent the warpage after forming the black film.

In the case where the substrate A is the black glass substrate, the Young's modulus of the glass in the substrate A is preferably 45 GPa or more from the viewpoint of reducing bending during conveyance due to its own weight.

<Substrate B>

The substrate B includes a plurality of holes. The plurality of holes is provided in order to provide one or more LED elements in each the holes. Here, light interference is likely to occur between adjacent LED elements, and due to this, a phenomenon in which a subtle change in a pixel pitch appears as streaky light (a connection streak) may occur. In the substrate B, since the LED elements provided in each of the holes are separated from each other by partition walls of the glass, light interference between the LED elements is less likely to occur. As a result, an image display device using the substrate B has no unevenness of the connection streak, and image quality can be improved.

In addition, although the LED light tends to head more toward the lateral direction than toward the front direction, by installing the LED element in each of the holes, it is possible to reflect the light on an inner surface of each of the holes and to reflect the light in the lateral direction toward the front surface (the black main surface of the substrate). Accordingly, light extraction efficiency is improved, and the power consumption can be reduced.

Each of the holes in the substrate B preferably penetrate the substrate. In addition, it is preferable that the LED element is provided on a main surface side facing the black main surface of the substrate, in each of the holes.

An interval between the holes is preferably 20 μm to 10,000 μm from the viewpoint of resolution.

In the substrate B, the shape of each of the holes viewed from the black main surface of the substrate is not particularly limited, and examples thereof include a circular shape, a quadrangular shape, and an L shape.

The size of each of the holes viewed from the black main surface of the substrate is not limited as long as it is sufficient to provide the LED element, and is preferably 100 μm² to 1,000,000 μm² from the viewpoint of ensuring an area of the black main surface.

In the substrate B, the shape of each of the holes viewed from the side surface of the substrate is not particularly limited, and examples thereof include a tubular shape, a tapered shape, and a substantially elliptical shape. Among these, the tapered shape, which is a shape that widens from an LED mounting surface side of the substrate toward the black main surface side, is preferable from the viewpoint of improving front luminance and contrast ratio.

FIG. 3 is a cross-sectional view of an image display device 1 including the LED element substrate B that includes a plurality of holes 13 each having tapered shape. The tapered shape is preferably designed so that the LED light can be efficiently reflected and the black main surface can be ensured. Such an angle is, for example, preferably 45° to 90°, more preferably 60° to 88°, further preferably 70° to 86°, and particularly preferably 75° to 85° as a taper angle θ shown in FIG. 3.

Examples of a method for forming the plurality of holes on the glass include known methods such as laser processing and etching.

In addition, from the viewpoint of improving the light extraction efficiency, it is preferable that a reflective film is provided on an inner surface of each of the holes in order to improve the reflectance in each of the holes.

As a material constituting the reflective film, a metal thin film or an alloy thin film of Al, Ag, or the like or a white ink having both high reflectance and scattering property is preferable in order to obtain a high reflectance.

The film thickness of the reflective film is preferably 30 nm to 2000 nm, and more preferably 100 nm to 1000 nm, from the viewpoint of improving the light extraction efficiency.

In addition, the reflective film is preferably provided on at least a part of the surface inside each of the holes, more preferably on the entire surface of each of the holes.

As a method for forming the reflective film on the inner surface of each of the holes, a known method such as sputtering or ink jet is used.

In the case where the substrate B is a glass substrate with a black film, the thickness of the substrate B is not limited as long as the thickness is larger than a height of the LED element, and is preferably 0.4 mm or more, more preferably 0.5 mm or more, and further preferably 0.7 mm or more in order to prevent the warpage after forming the black film. From the viewpoint of a degree of difficulty in drilling, the thickness is preferably 3.0 mm or less, and more preferably 2.0 mm or less.

In the case where the substrate B is a black glass substrate, the thickness is preferably 0.5 mm or more, more preferably 0.7 mm or more, further preferably 1.1 mm or more, from the viewpoint of preventing light transmission to the back surface of the substrate, and is preferably 3.0 mm or less, and more preferably 2.0 mm or less from the viewpoint of a degree of difficulty of a plural holes formation processing.

In the case where the substrate B is a glass substrate with the black film, the average thermal expansion coefficient of the substrate B at 50° C. to 350° C. is preferably from 20×10⁻⁷/° C. to 130×10⁻⁷/° C., more preferably from 30×10⁻⁷/° C. to 110×10⁻⁷/° C., and particularly preferably from 35×10⁻⁷/° C. to 95×10⁻⁷/° C., in order to match with a thermal expansion coefficient of a support to be described later and to prevent the warpage after forming the black film.

In the case where the substrate B is a black glass substrate, the average thermal expansion coefficient of the substrate B at 50° C. to 350° C. is preferably from 30×10⁻⁷/° C. to 110×10⁻⁷/° C., more preferably from 35×10⁻⁷/° C. to 95×10⁻⁷/° C., and particularly preferably from 38×10⁻⁷/° C. to 90×10⁻⁷/° C., in order to match with a thermal expansion coefficient of a support to be described later.

<Image Display Device>

The image display device according to the present invention includes the substrate according to the present invention and an LED element.

Since the substrate according to the present invention is suitable for the image display device, it is preferable that the LED element in the present invention is a three-color LED type element which is one light emitting source by including one or more of a red LED, a green LED, and a blue LED.

In the case where the substrate is the substrate A including no holes, the LED element is provided on the black main surface of the substrate.

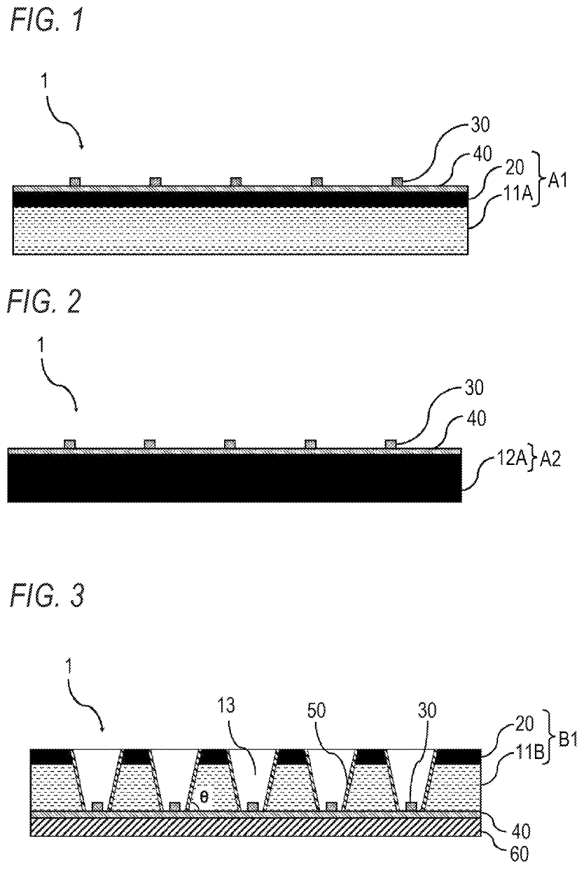

FIG. 1 is a cross-sectional view of the image display device 1 including an LED element substrate A1, which includes a non-colored glass substrate 11A and a black film 20, and LED elements 30.

FIG. 2 is a cross-sectional view of the image display device 1 including an LED element substrate A2, which includes a black glass substrate 12A, and the LED elements 30.

In FIGS. 1 and 2, a TFT layer 40 for a circuit is provided between the LED element substrate A1 or A2 and the LED elements 30. The TFT layer is generally a translucent thin film, and does not affect a black color of the main surface of the LED element substrate.

In the case where the substrate is the substrate B including the plurality of holes, at least one or more LED elements are provided in each of the holes.

FIG. 3 is a cross-sectional view of the image display device 1 including an LED element substrate B1, which includes a non-colored glass substrate 11B, the black film 20 and the plurality of holes 13, the LED elements 30 provided in each of the holes, and a support 60 for mounting the LED elements 30.

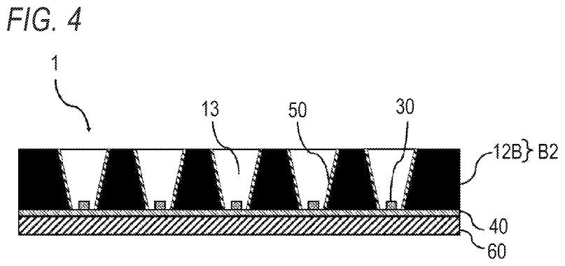

FIG. 4 is a cross-sectional view of the image display device 1 including an LED element substrate B2, which includes a black glass substrate 12B and the plurality of holes 13, the LED elements 30 provided in each of the holes, and the support 60 for mounting the LED elements 30.

In FIGS. 3 and 4, a reflective film 50 is provided on an inner surface of each of the holes.

In addition, in FIGS. 3 and 4, the TFT layer 40 for the circuit is provided between the support 60 and the LED elements 30.

In the image display device according to the present invention, the substrate according to the present invention is included as a mounting substrate for the LED element, so that the contrast ratio is good, and deterioration due to ultraviolet rays, moisture, or the like hardly occurs. Therefore, the substrate according to the present invention is particularly suitable for outdoor use.

### EXAMPLES

Hereinafter, the substrate according to the present invention will be described with reference to Examples, and the present invention is not limited to the Examples.

Values shown in parentheses in the table are calculated values or estimated values.

### Examples 1 to 10: Black Glass LED Element Substrate

In the following, Examples 1 to 8 are working examples, and Examples 9 to 10 are comparative examples.

Raw materials of the respective components were blended so that the glass composition became a target composition (unit: mol %) shown in Examples 1 to 10, and dissolved in a platinum crucible at 1600° C. for 3 hours. After dissolution, a molten liquid was allowed to flow on a carbon plate, held at a temperature of the glass transition point+30° C. for 60 minutes, and cooled to a room temperature (25° C.) at 1° C. per minute to obtain a sheet-shaped glass. The sheet-shaped glass was subjected to mirror polishing to obtain a glass sheet, and various evaluations of the average thermal expansion coefficient, the Young's modulus, and the absorption coefficient were performed.

(Average Thermal Expansion Coefficient)

The average thermal expansion coefficient was measured using a differential thermal dilatometer (TMA) in accordance with a method specified in JIS R 3102 (1995). A measurement temperature range was from room temperature to 400° C. or higher, and the average thermal expansion coefficient at 50° C. to 350° C. was represented in units of 10⁻⁷/° C.

(Young's Modulus)

The Young's Modulus was measured by a bending resonance method in accordance with a method specified in JIS R 1602 (1995).

Results are shown in Table 1.

TABLE 1

| | Example 1 | Example 2 | Example 3 | Example 4 | Example 5 |
|---|---|---|---|---|---|
| SiO₂ | 59.5 | 58.1 | 62.1 | 62.2 | 64.3 |
| B₂O₃ | 0 | 0 | 7.2 | 7.2 | 7.5 |
| Na₂O | 11.5 | 11.3 | 0 | 0 | 0 |
| K₂O | 3.8 | 3.6 | 0 | 0 | 0 |
| MgO | 9.7 | 9.5 | 5.3 | 5.3 | 5.5 |
| CaO | 0 | 0 | 4.6 | 4.6 | 4.8 |
| SrO | 0 | 0 | 4.6 | 4.6 | 4.8 |
| BaO | 0 | 0 | 0 | 0 | 0 |
| Al₂O₃ | 7.5 | 7.3 | 10.2 | 10.3 | 10.7 |
| TiO₂ | 0 | 0.2 | 0 | 0 | 0 |
| ZrO₂ | 0.5 | 0.5 | 0 | 0 | 0 |
| CeO₂ | 0 | 0 | 0 | 0 | 0 |
| Co₃O₄ | 0.76 | 0.3 | 0.18 | 0.18 | 0.25 |
| MnO₂ | 0 | 0 | 0 | 0 | 0 |
| Fe₂O₃ | 6.3 | 6.1 | 3.1 | 3.1 | 2.1 |
| Er₂O₃ | 0 | 0 | 1.17 | 0 | 0 |
| NiO | 0 | 2.6 | 1.02 | 1.02 | 0 |
| CuO | 0 | 0 | 0 | 0 | 0 |
| Cr₂O₃ | 0.02 | 0 | 0 | 0 | 0 |
| V₂O₅ | 0 | 0.1 | 0 | 0 | 0 |
| Bi₂O₃ | 0 | 0 | 0.5 | 0 | 0 |
| Nd₂O₃ | 0 | 0 | 0 | 1.47 | 0 |
| SO₃ | 0.37 | 0.37 | 0.001 | 0.001 | 0.001 |
| CeO₂ + Co₃O₄ + MnO₂ + Fe₂O₃ + | 7.1 | 9.1 | 6.0 | 5.8 | 2.4 |
| Er₂O₃ + NiO + CuO + Cr₂O₃ + | | | | | |
| V₂O₅ + Bi₂O₃ + Nd₂O₃ | | | | | |
| Average thermal expansion | (80) | (80) | (40) | (40) | (40) |
| coefficient (×10⁻⁷/° C.) | | | | | |
| Young's modulus (GPa) | (75) | (75) | (80) | (80) | (80) |
| Sheet thickness (mm) | 0.7 | 0.7 | 0.7 | 0.7 | 0.7 |
| Absorption coefficient (mm⁻¹) | (≥0.5) | (≥0.5) | (≥0.5) | (≥0.5) | (≥0.5) |
| (minimum value at wavelength of | | | | | |
| 380 nm to 650 nm) | | | | | |
| ΔT(550/600)(%) | (≤1.0) | (≤1.0) | (≤1.0) | (≤1.0) | (≤1.0) |
| ΔT(450/600)(%) | (≤1.0) | (≤1.0) | (≤1.0) | (≤1.0) | (≤1.0) |
| | Example 6 | Example 7 | Example 8 | Example 9 | Example 10 |
| SiO₂ | 60.5 | 63.5 | 63.5 | 65.7 | 66.5 |
| B₂O₃ | 1.1 | 1.1 | 1.1 | 7.7 | 1.2 |
| Na₂O | 0 | 0 | 0 | 0 | 0 |
| K₂O | 0 | 0 | 0 | 0 | 0 |
| MgO | 8.2 | 8.6 | 8.6 | 5.6 | 9 |
| CaO | 4.8 | 5 | 5 | 4.9 | 5.3 |
| SrO | 4 | 4.2 | 4.2 | 4.9 | 4.4 |
| BaO | 0.03 | 0.05 | 0.2 | 0 | 0.1 |
| Al₂O₃ | 11.8 | 12.5 | 12.5 | 10.9 | 13.0 |
| TiO₂ | 0 | 0 | 0 | 0 | 0 |
| ZrO₂ | 0 | 0 | 0 | 0 | 0 |
| CeO₂ | 2.5 | 0 | 0 | 0 | 0 |
| Co₃O₄ | 0.5 | 0.18 | 0.2 | 0.01 | 0.02 |
| MnO₂ | 0 | 0.75 | 0 | 0.03 | 0 |
| Fe₂O₃ | 0.1 | 3.1 | 0.1 | 0.2 | 0.01 |
| Er₂O₃ | 0 | 0 | 0 | 0 | 0 |
| NiO | 6.5 | 1.02 | 2.2 | 0.03 | 0.22 |
| CuO | 0 | 0 | 2.4 | 0 | 0.24 |
| Cr₂O₃ | 0 | 0 | 0 | 0 | 0 |
| V₂O₅ | 0 | 0 | 0 | 0 | 0 |
| Bi₂O₃ | 0 | 0 | 0 | 0 | 0 |
| Nd₂O₃ | 0 | 0 | 0 | 0 | 0 |
| SO₃ | 0.001 | 0.001 | 0.001 | 0.001 | 0.001 |
| CeO₂ + Co₃O₄ + MnO₂ + Fe₂O₃ + | 9.6 | 5.1 | 4.9 | 0.3 | 0.5 |
| Er₂O₃ + NiO + CuO + Cr₂O₃ + | | | | | |
| V₂O₅ + Bi₂O₃ + Nd₂O₃ | | | | | |
| Average thermal expansion | (40) | (40) | (40) | (40) | (40) |
| coefficient (×10⁻⁷/° C.) | | | | | |
| Young's modulus (GPa) | (90) | (90) | (90) | (80) | (90) |
| Sheet thickness (mm) | 0.7 | 0.7 | 0.7 | 0.7 | 0.7 |
| Absorption coefficient (mm⁻¹) | (≥0.5) | (≥0.5) | (≥0.5) | (<0.5) | (<0.5) |
| (minimum value at wavelength of | | | | | |
| 380 nm to 650 nm) | | | | | |
| ΔT(550/600)(%) | (≤1.0) | (≤1.0) | (≤1.0) | (Not | (Not |
| | | | | measured) | measured) |
| ΔT(450/600)(%) | (≤1.0) | (≤1.0) | (≤1.0) | (Not | (Not |
| | | | | measured) | measured) |

In the substrates in Examples 1 to 8 in which a total content of CeO₂, Co₃O₄, MnO₂, Fe₂O₃, Er₂O₃, NiO, CuO, Cr₂O₃, V₂O₅, Bi₂O₃, and Nd₂O₃ is in a suitable range (1 to 12 mol %), a minimum value of the absorption coefficient at a wavelength of 380 nm to 650 nm is 0.5 (mm⁻¹) or more. In addition, a change amount ΔT(550/600) and ΔT(450/600) of a relative value of the absorption coefficient are both 5% or less. That is, a black-colored glass substrate was obtained.

On the other hand, in Examples 9 and 10 in which the total amount of CeO₂, Co₃O₄, MnO₂, Fe₂O₃, Er₂O₃, NiO, CuO, Cr₂O₃, V₂O₅, Bi₂O₃, and Nd₂O₃ is less than 1 mol %, the minimum value of the absorption coefficient at the wavelength of 380 nm to 650 nm is less than 0.5 (mm⁻¹). That is, a black-colored glass substrate cannot be obtained.

In Examples 1 to 8, it is estimated that the absorption coefficient at a wavelength of 550 nm/the absorption coefficient at a wavelength of 600 nm, and the absorption coefficient at a wavelength of 450 nm/the absorption coefficient at a wavelength of 600 nm are both within a range of 0.7 to 1.2.

### Examples 11 to 13: LED Element Substrate Including Black Film

In the following, Examples 11 to 13 are working examples.

### Example 11

Raw materials of the respective components were blended so that the glass composition became a target composition (unit: mol %) shown in Example 11, and dissolved in a platinum crucible at 1600° C. for 3 hours. After dissolution, a molten liquid was allowed to flow on a carbon plate, held at a temperature of the glass transition point+30° C. for 60 minutes, and cooled to a room temperature (25° C.) at 1° C. per minute to obtain a colorless sheet-shaped glass. The sheet-shaped glass was subjected to mirror polishing to obtain a glass sheet, and various evaluations of the average thermal expansion coefficient, the Young's modulus, and the transmittance were performed.

The average thermal expansion coefficient and the Young's modulus are evaluated in the same manner as in Example 1.

The transmittance was measured using a spectrophotometer.

A chromium (Cr; extinction coefficient of 3.33) film, a copper oxide (CuO; refractive index of 2.58, extinction coefficient of 0.59) film, and a silicon oxide (SiO₂; refractive index of 1.47) film were sequentially laminated on one main surface of the colorless glass substrate obtained as described above by a sputtering method to form a black film (three layers) having a configuration as shown in the following table.

The LED element substrate was obtained by the method described above.

### Example 12

A colorless sheet-shaped glass was obtained in the same manner as in Example 11.

A tantalum oxide (Ta₂O₅; refractive index of 2.23) film, a copper oxide (CuO; refractive index of 2.58, extinction coefficient of 0.59) film, a chromium (Cr; extinction coefficient of 3.33) film, a copper oxide (CuO; refractive index of 2.58, extinction coefficient of 0.59) film, and a silicon oxide (SiO₂; refractive index of 1.47) film were sequentially laminated on one main surface of the obtained colorless glass substrate by a sputtering method to form a black film (five layers) having a configuration as shown in the following table.

The LED element substrate was obtained by the method described above.

### Example 13

A colorless sheet-shaped glass was obtained in the same manner as in Example 11.

A chromium (Cr; extinction coefficient of 3.33) film, a lower chromium oxide (CrOx) film, a chromium (Cr; extinction coefficient of 3.33) film, a lower chromium oxide film, and a silicon oxide (SiO₂; refractive index of 1.47) film were sequentially laminated on one main surface of the obtained colorless glass substrate by a sputtering method to form a black film (five layers) having a configuration as shown in the following table.

The LED element substrate was obtained by the method described above.

For the LED element substrates in Examples 11 to 13, an average transmittance and an average reflectance at a wavelength of 380 nm to 650 nm were measured by a spectrophotometer.

Further, in the case where the LED element substrates in Examples 11 to 13 included holes, an increase rate of an LED panel front luminance was evaluated by performing simulation using light ray tracing software (light tools: manufactured by Cybernet Systems Co.,Ltd.).

As a comparative model, a model in which a cubic LED of 0.1 mm square emitting Lambertian light was disposed at the center on a main surface of a transparent glass substrate having a thickness of 1 mm and a size of 100 mm×100 mm was prepared.

As the LED element substrate including the holes in Example 11, a substrate, in which a substrate in Example 11 including a through hole designed to have a hole configuration shown in the following table was disposed on an LED arrangement surface in the comparative model so that the LED was accommodated in the hole, was prepared. The through hole was a truncated cone having a diameter of 0.5 mm on an observer side, that is, a front surface of a display device, and a diameter of 0.25 mm on a transparent substrate side, and the reflectance of an inner wall surface of the hole was set to a value shown in the following table.

The number of light beams in the simulation was 100,000.

The LED panel front luminance of the comparative model and the LED panel front luminance of the LED element substrate including the holes in Example 11 were compared, and the increase rates were calculated. In the case where the increase rate was 1 or more, it was evaluated that the contrast ratio was improved.

In each of Examples 12 to 13, the increase rate of the LED panel front luminance was calculated in the same manner.

Results are shown in the following table.

TABLE 2

| | | Example 11 | | Example 12 | | Example 13 | |
|---|---|---|---|---|---|---|---|
| Glass | SiO₂ | 65.8 | | 65.8 | | 65.8 | |
| substrate | B₂O₃ | 7.8 | | 7.8 | | 7.8 | |
| composition | Na₂O | 0.07 | | 0.07 | | 0.07 | |
| (mol %) | K₂O | 0.01 | | 0.01 | | 0.01 | |
| | MgO | 5.7 | | 5.7 | | 5.7 | |
| | CaO | 4.8 | | 4.8 | | 4.8 | |
| | SrO | 5.0 | | 5.0 | | 5.0 | |
| | BaO | 0 | | 0 | | 0 | |
| | Al₂O₃ | 10.8 | | 10.8 | | 10.8 | |
| | TiO₂ | 0 | | 0 | | 0 | |
| | ZrO₂ | 0.01 | | 0.01 | | 0.01 | |
| Glass | Average | 38 | | 38 | | 38 | |
| substrate | thermal | | | | | | |
| physical | expansion | | | | | | |
| properties | coefficient | | | | | | |
| | (×10⁻⁷/° C.) | | | | | | |
| | Young's | 77 | | 77 | | 77 | |
| | modulus | | | | | | |
| | (GPa) | | | | | | |
| | Transmittance (%) | | | | | | |
| | (minimum value at | | | | | | |
| | wavelength of 380 | | | | | | |
| | nm to 650 nm) | 88 | | 88 | | 90 | |
| | | | Film | | Film | | Film |
| | | | thickness | | thickness | | thickness |
| | | Material | (nm) | Material | (nm) | Material | (nm) |
| Black film | First layer | Cr | 150 | Ta₂O₅ | 14.1 | Cr | 150 |
| configuration | Second layer | CuO | 35.6 | CuO | 35.6 | CrOx | 41.6 |
| | Third layer | SiO₂ | 53.4 | Cr | 150 | Cr | 9.3 |
| | Fourth layer | — | — | CuO | 35.6 | CrOx | 25.8 |
| | Fifth layer | — | — | SiO₂ | 53.4 | SiO₂ | 52.7 |

| | | | | |
|---|---|---|---|---|
| Hole | Glass substrate | 100 × 100 | 300 × 300 | 920 × 730 |
| configuration | dimension (mm) | | | |
| | Glass sheet | 1.0 | 1.0 | 0.5 |
| | thickness (mm) | | | |
| | Hole shape | Circular | Circular | Rectangle |
| | Hole size (back | Φ0.25 | Φ0.5 | Vertical 3.0 × |
| | side, mm) | | | horizontal 1.5 |
| | Hole arrangement | Vertical 2.0 × | Vertical 2.0 × | Vertical 8.0 × |
| | interval (mm) | horizontal 2.0 | horizontal 2.0 | horizontal 9.0 |
| | Taper angle θ (°) | (82.875) | (90) | (80) |
| | in FIG. 3 | | | |
| | Reflectance (%) of | (95) | (95) | (85) |
| | inner wall surface | | | |
| | of hole | | | |
| LED | Average | (≤0.2) | (≤0.2) | (≤0.2) |
| element | transmittance (%) at | | | |
| substrate | wavelength of 380 | | | |
| characteristics | nm to 650 nm | | | |
| | Average reflectance | (≤1.0) | (≤1.0) | (≤1.0) |
| | (%) at wavelength of | | | |
| | 380 nm to 650 nm | | | |
| | Appearance color | Black | Black | Black |
| | Contrast ratio | A | A | A |
| | improvement | | | |
| | Increase rate of | (1.36) | (1.06) | (≥1.1) |
| | LED panel front | | | |
| | luminance | | | |

From the above results, the front luminance calculated using the model was 1.36 times in Example 11 and 1.06 times in Example 12 with respect to the front luminance calculated using the comparative model including only the transparent glass and the LED disposed in the center on the main surface. Example 13 was estimated to have brightness of 1.1 times or more. In the simulation, the number of holes and the number of LEDs were one, and it was confirmed that the same effect can be obtained even with a large number of holes and LEDs. From this, it was found that, in the case where the taper angle θ shown in FIG. 3 is in a range of 45° to 90°, an image display device having a high front luminance and a large contrast ratio can be provided.

### Examples 14 to 21: Black Glass LED Element Substrate

In the following, Examples 14 to 21 are working examples.

Raw materials of the respective components were blended so that the glass composition became a target composition (unit: mol %) shown in Examples 14 to 21, and dissolved in a platinum crucible at 1600° C. for 3 hours. After dissolution, a molten liquid was allowed to flow on a carbon plate, held at a temperature of the glass transition point+30° C. for 60 minutes, and cooled to a room temperature (25° C.) at 1° C. per minute to obtain a black sheet-shaped glass. The sheet-shaped glass was subjected to mirror polishing to obtain a glass sheet, and various evaluations of the average thermal expansion coefficient, the Young's modulus, and the absorption coefficient were performed.

The average thermal expansion coefficient and the Young's modulus are evaluated in the same manner as in Example 1.

The LED element substrate was obtained by the method described above.

The average transmittance and the average reflectance at a wavelength of 380 nm to 650 nm and the increase rate of the LED panel front luminance in the case of including the holes were evaluated in the same manner as in Example 11.

Results are shown in the following table.

TABLE 3

| | | Example 14 | Example 15 | Example 16 | Example 17 |
|---|---|---|---|---|---|
| Glass | SiO₂ | 59.5 | 58.1 | 62.1 | 62.2 |
| substrate | B₂O₃ | 0 | 0 | 7.2 | 7.2 |
| composition | Na₂O | 11.5 | 11.3 | 0 | 0 |
| (mol %) | K₂O | 3.8 | 3.6 | 0 | 0 |
| | MgO | 9.7 | 9.5 | 5.3 | 5.3 |
| | CaO | 0 | 0 | 4.6 | 4.6 |
| | SrO | 0 | 0 | 4.6 | 4.6 |
| | BaO | 0 | 0 | 0 | 0 |
| | Al₂O₃ | 7.5 | 7.3 | 10.2 | 10.3 |
| | TiO₂ | 0 | 0.2 | 0 | 0 |
| | ZrO₂ | 0.5 | 0.5 | 0 | 0 |
| | CeO₂ | 0 | 0 | 0 | 0 |
| | Co₃O₄ | 0.76 | 0.3 | 0.18 | 0.18 |
| | MnO₂ | 0 | 0 | 0 | 0 |
| | Fe₂O₃ | 6.3 | 6.1 | 3.1 | 3.1 |
| | Er₂O₃ | 0 | 0 | 1.17 | 0 |
| | NiO | 0 | 2.6 | 1.02 | 1.02 |
| | CuO | 0 | 0 | 0 | 0 |
| | Cr₂O₃ | 0.02 | 0 | 0 | 0 |
| | V₂O₅ | 0 | 0.1 | 0 | 0 |
| | Bi₂O₃ | 0 | 0 | 0.5 | 0 |
| | Nd₂O₃ | 0 | 0 | 0 | 1.47 |
| | SO₃ | 0.37 | 0.37 | 0.001 | 0.001 |
| | CeO₂ + Co₃O₄ + | 7.1 | 9.1 | 6.0 | 5.8 |
| | MnO₂ + Fe₂O₃ + | | | | |
| | Er₂O₃ + NiO + CuO + | | | | |
| | Cr₂O₃ + V₂O₅ + | | | | |
| | Bi₂O₃ + Nd₂O₃ | | | | |
| Glass | Average | (80) | (80) | (40) | (40) |
| substrate | thermal | | | | |
| physical | expansion | | | | |
| properties | coefficient | | | | |
| | (×10⁻⁷/° C.) | | | | |
| | Young's modulus | (75) | (75) | (80) | (80) |
| | (GPa) | | | | |
| | Absorption | (≥0.5) | (≥0.5) | (≥0.5) | (≥0.5) |
| | coefficient (mm⁻¹) | | | | |
| | (minimum value at | | | | |
| | wavelength of 380 | | | | |
| | nm to 650 nm) | | | | |
| | AT(550/600)(%) | (≤1.0) | (≤1.0) | (≤1.0) | (≤1.0) |
| | AT(450/600)(%) | (≤1.0) | (≤1.0) | (≤1.0) | (≤1.0) |
| Hole | Glass substrate | 100 × 100 | 100 × 100 | 100 × 100 | 100 × 100 |
| configuration | dimension (mm) | | | | |
| | Glass sheet | 1.0 | 1.0 | 1.0 | 0.5 |
| | thickness (mm) | | | | |
| | Hole shape | Circular | Circular | Circular | Circular |
| | Hole size (back | Φ0.25 | Φ0.25 | Φ0.375 | Φ0.25 |
| | side, mm) | | | | |
| | Hole arrangement | Vertical 2.0 × | Vertical 2.0 × | Vertical 2.0 × | Vertical 2.0 × |
| | interval (mm) | horizontal 2.0 | horizontal 2.0 | horizontal 2.0 | horizontal 2.0 |
| | Taper angle θ (°) | (82.875) | (82.875) | (86.424) | (82.875) |
| | in FIG. 3 | | | | |
| | Reflectance (%) of | (85) | (95) | (95) | (85) |
| | inner wall surface | | | | |
| | of hole | | | | |
| LED element | Maximum value of | (≤0.2) | (≤0.2) | (≤0.2) | (≤0.2) |
| substrate | transmittance (%) at | | | | |
| characteristics | wavelength of 380 | | | | |
| | nm to 650 nm | | | | |
| | Maximum value of | (4.0) | (4.0) | (4.0) | (4.0) |
| | reflectance (%) at | | | | |
| | wavelength of 380 | | | | |
| | nm to 650 nm | | | | |
| | Appearance color | Black | Black | Black | Black |
| | Contrast ratio | A | A | A | A |
| | improvement | | | | |
| | Increase rate of LED | (3.36) | (1.87) | (1.36) | (>1.1) |
| | panel front luminance | | | | |

| | | Example 18 | Example 19 | Example 20 | Example 21 |
|---|---|---|---|---|---|
| Glass | SiO₂ | 64.3 | 60.5 | 63.5 | 63.5 |
| substrate | B₂O₃ | 7.5 | 1.1 | 1.1 | 1.1 |
| composition | Na₂O | 0 | 0 | 0 | 0 |
| (mol %) | K₂O | 0 | 0 | 0 | 0 |
| | MgO | 5.5 | 8.2 | 8.6 | 8.6 |
| | CaO | 4.8 | 4.8 | 5 | 5 |
| | SrO | 4.8 | 4 | 4.2 | 4.2 |
| | BaO | 0 | 0.03 | 0.05 | 0.2 |
| | Al₂O₃ | 10.7 | 11.8 | 12.5 | 12.5 |
| | TiO₂ | 0 | 0 | 0 | 0 |
| | ZrO₂ | 0 | 0 | 0 | 0 |
| | CeO₂ | 0 | 2.5 | 0 | 0 |
| | CO₃O₄ | 0.25 | 0.5 | 0.18 | 0.2 |
| | MnO₂ | 0 | 0 | 0.75 | 0 |
| | Fe₂O₃ | 2.1 | 0.1 | 3.1 | 0.1 |
| | Er₂O₃ | 0 | 0 | 0 | 0 |
| | NiO | 0 | 6.5 | 1.02 | 2.2 |
| | CuO | 0 | 0 | 0 | 2.4 |
| | Cr₂O₃ | 0 | 0 | 0 | 0 |
| | V₂O₅ | 0 | 0 | 0 | 0 |
| | Bi₂O₃ | 0 | 0 | 0 | 0 |
| | Nd₂O₃ | 0 | 0 | 0 | 0 |
| | SO₃ | 0.001 | 0.001 | 0.001 | 0.001 |
| | CeO₂ + Co₃O₄ + | 2.4 | 9.6 | 5.1 | 4.9 |
| | MnO₂ + Fe₂O₃ + | | | | |
| | Er₂O₃ + NiO + CuO + | | | | |
| | Cr₂O₃ + V₂O₅ + | | | | |
| | Bi₂O₃ + Nd₂O₃ | | | | |
| Glass | Average | (40) | (40) | (40) | (40) |
| substrate | thermal | | | | |
| physical | expansion | | | | |
| properties | coefficient | | | | |
| | (×10⁻⁷/° C.) | | | | |
| | Young's modulus (GPa) | (80) | (90) | (90) | (90) |
| | Absorption coefficient | (≥0.5) | (≥0.5) | (≥0.5) | (≥0.5) |
| | (mm⁻¹) (minimum | | | | |
| | value at wavelength of | | | | |
| | 380 nm to 650 nm) | | | | |
| | AT(550/600)(%) | (≤1.0) | (≤1.0) | (≤1.0) | (≤1.0) |
| | AT(450/600)(%) | (≤1.0) | (≤1.0) | (≤1.0) | (≤1.0) |
| Hole | Glass substrate | 100 × 100 | 100 × 100 | 100 × 100 | 100 × 100 |
| configuration | dimension (mm) | | | | |
| | Glass sheet | 0.5 | 0.5 | 0.5 | 1.0 |
| | thickness (mm) | | | | |
| | Hole shape | Circular | Circular | Rectangle | Circular |
| | Hole size (back | Φ0.25 | Φ0.375 | Vertical 3.0 × | Φ0.5 |
| | side, mm) | | | horizontal 1.5 | |
| | Hole arrangement | Vertical 2.0 × | Vertical 2.0 × | Vertical 8.0 × | Vertical 2.0 × |
| | interval (mm) | horizontal 2.0 | horizontal 2.0 | horizontal 9.0 | horizontal 2.0 |
| | Taper angle θ (°) | (86.424) | (86.424) | (80) | (90) |
| | in FIG. 3 | | | | |
| | Reflectance (%) of inner | (95) | (95) | (95) | (95) |
| | wall surface of hole | | | | |
| LED | Maximum value of | (≤0.2) | (≤0.2) | (≤0.2) | (≤0.2) |
| element | transmittance (%) at | | | | |
| substrate | wavelength of 380 nm | | | | |
| characteristics | to 650 nm | | | | |
| | Maximum value of | (4.0) | (4.0) | (4.0) | (4.0) |
| | reflectance (%) at | | | | |
| | wavelength of 380 nm | | | | |
| | to 650 nm | | | | |
| | Appearance color | Black | Black | Black | Black |
| | Contrast ratio | A | A | A | A |
| | improvement | | | | |
| | Increase rate of LED | (≥1.1) | (≥1.1) | (≥1.1) | (≥1.0) |
| | panel front luminance | | | | |

From the above results, the front luminance calculated using the model was 3.36 times in Example 14, 1.87 times in Example 15, and 1.36 times in Example 16 with respect to the front luminance calculated using the comparative model including only the transparent glass and the LED disposed in the center on the main surface. Examples 17 to 20 were estimated to have brightness of 1.1 times or more. In addition, it was estimated that Example 21 in which the taper angle θ shown in FIG. 3 was 90° also had a brightness of 1.0 times or more. In the simulation, the number of holes and the number of LEDs were one, and it was confirmed that the same effect can be obtained even with a large number of holes and LEDs. From this, it was found that, in the case where the taper angle θ shown in FIG. 3 is in a range of 45° to 90°, an image display device having a high front luminance and a large contrast ratio can be provided.

Although the present invention has been described in detail with reference to specific embodiments, it is apparent to those skilled in the art that various changes and modifications can be made without departing from the spirit and scope of the present invention. The present application is based on a Japanese Patent Application (No. 2020-153811) filed on Sep. 14, 2020, the contents of which are incorporated herein by reference.

### INDUSTRIAL APPLICABILITY

A substrate according to the present invention is useful for an LED image display device mounted on a large vision, a street advertisement, a digital camera, an in-vehicle display, a notebook PC, a tablet terminal, or the like because a contrast ratio does not decrease in the case where an LED element is mounted and deterioration due to ultraviolet rays or moisture hardly occurs, and is particularly suitable for an LED image display device used outdoors.

### REFERENCE SIGNS LIST

1 Image display device
A1, A2, B1, B2 LED element substrate
11A, 11B, 12A, 12B Glass substrate
13 A plurality of holes
20 Black film
30 LED element
40 TFT layer
50 Reflective film
60 Support

1. An LED element substrate on which an LED element is to be provided and which comprises a glass, wherein
at least one main surface of the substrate is black, and
one or more LED elements are to be provided on the black main surface.

2. An LED element substrate on which an LED element is to be provided and which comprises a glass, wherein
at least one main surface of the substrate is black,
the substrate comprises a plurality of holes, and
one or more LED elements are to be provided on an inside of each of the holes.

3. The LED element substrate according to claim 2, wherein each of the holes has a tapered shape.

4. The LED element substrate according to claim 2, wherein each of the holes comprises a reflective film on an inner surface of each of the holes.

5. The LED element substrate according to claim 1, wherein the glass is colored black or comprises a black film on at least one main surface of the substrate.

6. An image display device comprising: the LED element substrate according to claim 1; and an LED element.
